(19) United States
(12) Patent Application Publication
(10) Pub. No.: US 2008/0308904 A1
(43) Pub. Date: Dec. 18, 2008

(54) P-DOPED REGION WITH IMPROVED ABRUPTNESS

(75) Inventors: P. R. Chidambaram, Richardson, TX (US); Srinivasan Chakravarthi, Murphy, TX (US); Mahalingam Nandakumar, Richardson, TX (US); Manoj Mehrotra, Plano, TX (US); Amitabh Jain, Allen, TX (US); Thomas D. Bonifield, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/763,497

(22) Filed: Jun. 15, 2007

(51) Int. Cl. H01L 21/425; H01L 29/36

(52) U.S. Cl. 257/607; 438/528; 257/E29.109; 257/E21.473

(57) ABSTRACT

A method of manufacturing a semiconductor device. The method comprises providing C atoms in a semiconductor substrate. The method also comprises implanting In atoms and p-type dopants into a predefined region of the substrate that is configured to have the carbon atoms. The method further comprises thermally annealing the semiconductor substrate to transform the predefined region into an activated doped region.

### TECHNICAL FIELD

The disclosure is directed, in general, to semiconductor devices and the manufacture of semiconductor devices, and more specifically, to forming a predefined doped region in a semiconductor substrate to enhance the performance of the device.

### BACKGROUND

As semiconductor devices become more complex and smaller, power consumption has become an important limiting factor to the pace of device design and manufacturing. One problem limiting further reductions in device sizes is the excessive diffusion of certain dopants. When an implanted dopant diffuses farther than desired, the definition of a doped region may not be as sharp as desired. A diffusely defined doped region can cause short channel effects where two or more doped regions merge together. Short channel effects, in turn, can cause an unacceptably high off-state current leakage.

Accordingly, what is needed is a method for forming doped regions in semiconductor device that addresses the drawbacks of the prior art methods and devices.

### SUMMARY

The disclosure provides a method of manufacturing a semiconductor device. The method comprises providing carbon atoms in a semiconductor substrate. The method also comprises implanting indium atoms and p-type dopants into a predefined region of the substrate that is configured to have the carbon atoms. The method further comprises thermally annealing the semiconductor substrate to transform the predefined region into an activated doped region.

Another embodiment of manufacturing the device, comprises forming one or more active devices on or in a semiconductor substrate. At least one of the active devices is manufactured by a process that includes providing carbon atoms, implanting indium and boron atoms and thermally annealing as described above.

Another embodiment is a semiconductor device comprising one or more active devices on or in a semiconductor substrate. At least one of the active devices has one or more activated p-doped regions that includes carbon atoms, indium atoms and p-type dopants.

### BRIEF DESCRIPTION OF DRAWINGS

The disclosure is described with reference to example embodiments and to accompanying drawings, wherein:

FIG. 1 presents a flow diagram of an example method of manufacturing a semiconductor device of the present disclosure; and

FIGS. 2 to 5 illustrate cross-section views of selected steps in example methods of manufacturing a semiconductor device of the disclosure.

### DETAILED DESCRIPTION

The present disclosure includes the discovery that inclusion of both indium (In) and carbon (C) atoms in a p-type doped region of substrate provides several beneficial effects to facilitate the formation of doped regions in a semiconductor substrate. The In atoms help to retard the diffusion of the p-type dopants out of the doped region during an activating thermal anneal. While not limiting the scope of the disclosure by theory, it is believed that In and C atoms form bonding pair associations in adjacent substitutional sites in the lattice structure of the substrate (e.g., silicon). Consequently, high concentrations of both of the In and C atoms are maintained in the doped region because both atom types are less prone to diffuse in each other's presence. The high concentration of C atoms, in turn, helps to retard the diffusion of implanted p-type dopants. The high concentration of In, which also has p-type characteristics, also supplements the p-type dopants in the p-doped region, thereby increasing the region's conductivity. Additionally, in some cases, the implantation of In can amorphize the substrate, thereby helping to prevent implanted C atoms from penetrating to excessive depths through channeling into the substrate.

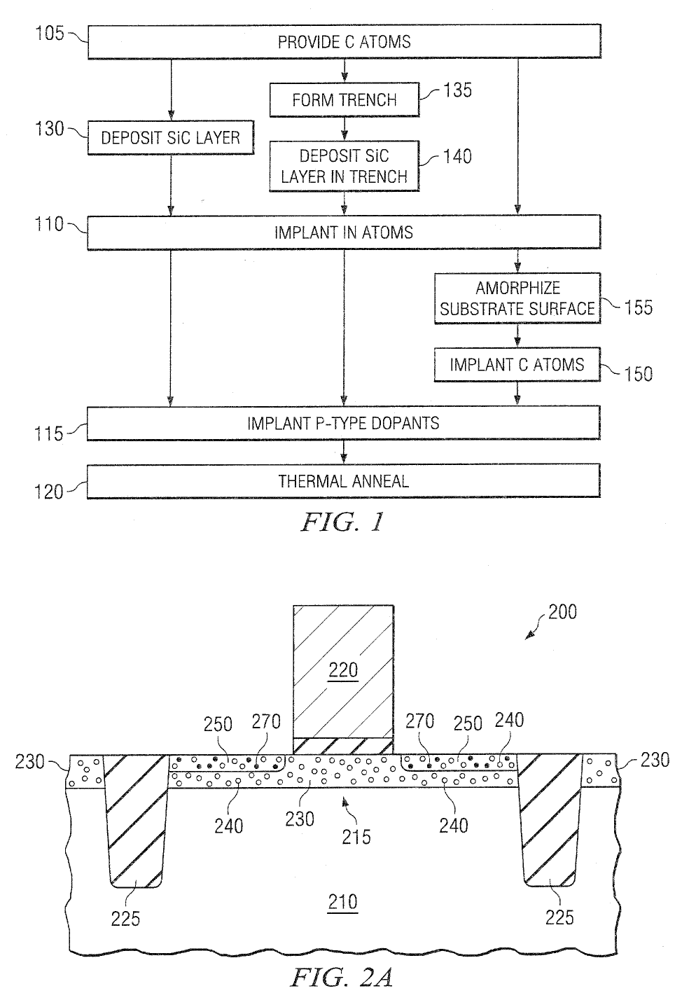

FIG. 1 presents a flow diagram of an example method of manufacturing a semiconductor device of the present disclosure. As shown in FIG. 1, the method includes providing C atoms in a semiconductor substrate (step 105). The method also includes implanting In atom into a predefined region of the substrate (step 110) and implanting p-type dopants into the predefined region (step 115). The predefined region is that is configured to have the C atoms. E.g., in some cases, the predefined region has C atoms before In atom implantation, while in other cases the C atoms are provided after In atom implantation. The method further includes thermally annealing the substrate to transform the predefined region into an activated doped region (step 120).

The term predefined region as used herein refers to a portion of the substrate targeted to receive p-type dopants via ion implantation. As used herein p-type dopants refers to any atoms having p-type characteristics other than indium; typically the p-type dopant is boron. The term activated p-doped region as used herein refers to the portion of the substrate having the bulk of the implanted p-type dopants after the thermal anneal. Those skilled in the art would understand how the thermal anneal diffuses and electrically activates the p-type dopants by increasing the p-type dopant's population in substitutional sites of the substrate. E.g., following the thermal anneal, the activated p-doped region has an at least about 10 times increase in the electrical conductivity as compared to before the anneal.

There are several ways in which the carbon atoms can be provided in step 105. In some embodiments, providing the carbon atoms includes depositing a silicon carbide (SiC) layer on the semiconductor substrate (step 130). In other embodiments, providing the C atoms in the substrate includes forming a trench in the semiconductor substrate (step 135) and then depositing a SiC layer in the trench (step 140). In still other embodiments, providing the C atoms includes implanting C atoms into the semiconductor substrate (step 150).

In some cases it is preferable, for the In atoms to be implanted (step 110) before the implantation of C atoms (step 150). The In atom implantation can be further configured, in step 155, to amorphize a surface of the substrate, in particular the portion of the surface that the C atoms are implanted into. As well understood by those skilled in the art, an amorphized semiconductor surface is one that has lost its crystallinity and become substantially disordered. Pre-amorphizing the surface of the substrate that the C atoms will be implanted into helps to prevent the excessive penetration of the C atoms into the substrate. That is, pre-amorphization helps to localize the implantation of the C atoms into the predefined region.

In other cases, such as when the C atoms are provided by depositing the SiC layer on or in the substrate (e.g., steps 130 or step 140), In atoms can be implanted in step 110 after providing the C atoms. In such cases, the In atoms can be implanted into the SiC layer, and in particular, into a predefined region located within the SiC layer. Regardless of whether they are implanted before or after the C atoms any number of conventional implantion tools and process can be used to implant the In atoms during step 110. E.g., normal or abnormal angled ion implants can be done using indium trichloride or indium oxide as the source material.

Similarly, the implantation of p-type dopants in step 115 can be accomplished using conventional tools and process. E.g., normal or abnormal angled ion implants can be done using boron or BF₂ as the source material. In some embodiments, the p-type dopant comprises boron or boron difluoride (BF₂) as the source implantation material. One advantage in implanting BF₂ is that the F atoms can perform a similar function to the C atoms of retarding the diffusion of B atoms during the thermal anneal step 120. When BF₂ is used as the source material for p-type dopant implantation, there is a substantially equal or greater dose of fluorine atoms implanted as the p-type dopant (B).

As noted above, bonding pair associations between In and C in adjacent substitional sites in the substrate are though to help retard the diffusion of both atoms and p-type dopants during the thermal anneal step 120. E.g., C atoms impede the diffusion of the implanted In atoms, and In atoms impede the diffusion of implanted C atoms. It is therefore desirable for a substantial number of the implanted In and C atoms to occupy adjacent substitutional sites in the semiconductor substrate. E.g., in some case at least about 1 percent of the adjacent substitutional sites in a predefined region of a silicon substrate are occupied by In and C atoms.

It is desirable for the C atoms to be provided in step 105 at sufficient concentrations to impede the diffusion of both the In atoms and the p-type dopants. E.g., in some embodiments a dose of the deposited (steps 130 or 140) or implanted (step 150) C atoms in the predefined region is greater than or equal to a sum of doses of the In atoms and the p-type dopants in the predefined region.

The thermal anneal step 120 is configured to transform the predefined region into an activated doped region. Because the In and C atoms retard the diffusion of the p-type dopants during the thermal anneal step 120, the activated doped region has a more abrupt boundary than obtain by the same thermal anneal, but with no In atoms present. E.g., in some embodiments the activated p-doped region has an abrupt boundary as characterized by a decade change in the p-type dopant concentration over a distance of about 7 nm or less, and in some cases about 5 nm or less.

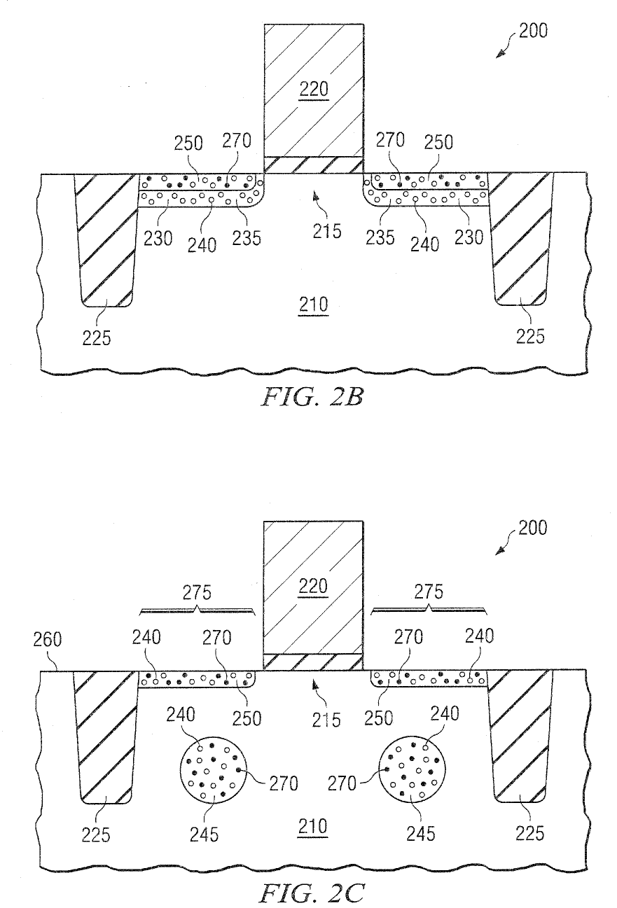

To further illustrate aspects of the disclosure, FIGS. 2 to 5 illustrate cross-section views of selected steps in example methods of manufacturing a semiconductor device of the disclosure. The method comprises forming one or more active devices on or in a semiconductor substrate, wherein at least one of said active devices is manufactured by a process that includes the process presented above in the context of FIG. 1.

With continuing reference to FIG. 1, FIGS. 2A-2B shows alternative embodiments of the semiconductor device 200 after providing C atoms in a semiconductor substrate 210 for at least one active device 215, in accordance with step 105.

As illustrated in FIGS. 2A-2C other device components may be fabricated before performing the steps described in FIG. 1. E.g., conventional process can be used to form a gate 220 of the active device 215, as well as isolation structures 225 (e.g., shallow trench isolation or field oxides) to e.g., electrically isolate the active device 215 from other active components of the device 200.

FIG. 2A shows the device 200 after depositing a SiC layer 230, containing C atoms 240, on the substrate 210 (step 130). E.g., a blanket epitaxial layer of SiC 230 can be grown on a silicon substrate 210 by conventional procedures such as the simultaneous chemical vapor phase deposition (CVD) of silicon from silicon tetrachloride or silane source gases and carbon from conventional source gases.

FIG. 2B shows the device 200 forming a trench 235 in the substrate 210 (step 135) and then depositing a SiC layer 230 in the trench 235 (step 140). The trench 235 can be formed in step 135 by any number of etching processes to remove portions of the silicon substrate 210 using, e.g., reactive ion etching (e.g., a reactive ion etch comprising HBr), or other conventional etching processes. Depositing the SiC layer 230 in the trench (step 140) can be accomplished using substantially the same processes as used to deposit the SiC layer 230 in step 130 (FIG. 2A).

FIG. 2C shows the device 200 after implanting C atoms 240 into the substrate 210 (step 150). As illustrated in FIG. 2C, the C atoms 240 can be implanted into one or more predefined regions 245, 250 of the substrate 210. Any conventional ion implantation tool or process can be used to implant the C atoms. The implantation of the C atoms 240 may be normal to the substrate surface 260 or abnormal (e.g., angled implants) to the surface 260. In some cases, the predefined region 245 is configured as one or more halo pre-anneal regions. Examples of halo pre-anneal regions are presented in U.S. Pat. No. 7,061,058 to Chakravarthi et al., which is incorporated by reference herein in its entirety. In other cases, the predefined region 250 is configured as source and drain pre-anneal regions. As shown in FIG. 2C, embodiments of the active device 215 can have both of the halo and source and drain pre-anneal regions 245, 250.

FIG. 2C also shows the device after implanting In atoms 270 into the predefined regions 245, 250 in accordance with step 110. As discussed above in the context of FIG. 1, it is desirable to implant the In atoms 270 before implanting the C atoms 240. E.g., in some instances, In atom 270 implantation is configured to amorphize a portion 275 of the substrate surface 260.

In other cases, In atoms can be implanted after providing the C atoms. E.g., FIG. 2A shows the device 200 after implanting the In atoms 270 (step 110) into lightly doped drain pre-anneal regions 250 that are located within the SiC layer 230. FIG. 2B shows the device 200 after implanting the In atoms 270 (step 110) into lightly doped drain pre-anneal regions 250 that are located within the SiC layer 230 located within the trench 235.

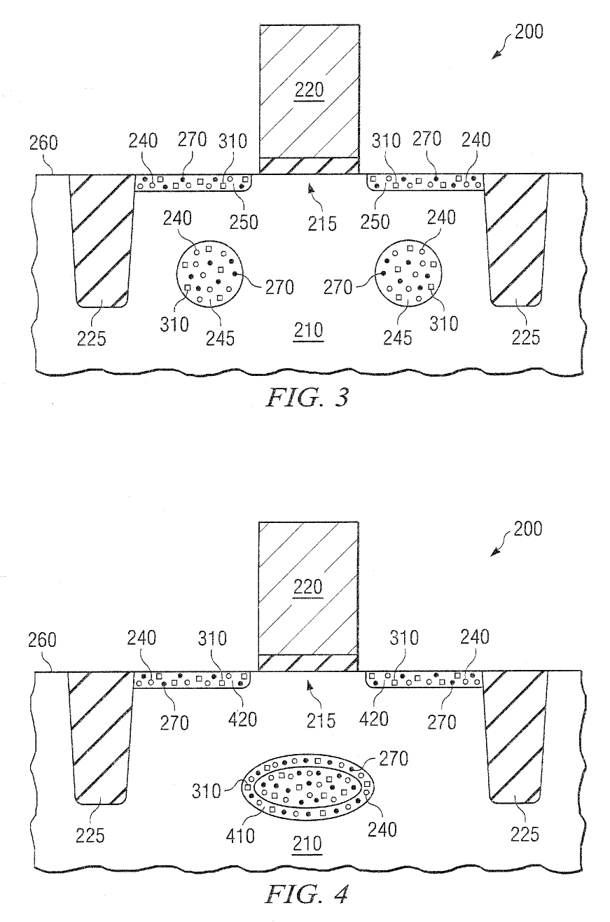

FIG. 3 shows the device 200 presented in FIG. 2C after implanting boron atoms 310 (e.g., B or BF₂) into the predefined regions 245, 250 of the substrate 210 (step 115, FIG. 1). Analogous procedures can be used to implant boron into the embodiments of the devices shown in FIGS. 2A and 2B (not shown).

It is important, and sometimes critical, that the dose and acceleration energy of the different implanted atoms be adjusted within a range configured to locate the atoms into the designated predefined region 245, 250.

E.g., consider the case where the predefined region 245 is configured as halo pre-anneal regions, and C atoms 240 are provided by implantation. In some embodiments, implanting the C atoms 240 into the semiconductor substrate 210 includes a dose of about 1E15 to 2E15 atoms/cm² and acceleration energy of about 1 to 5 keV. Implanting the In atoms 270 includes a dose of about 1E13 to 6E13 atom/cm² and acceleration energy of about 4 to 8 keV. Implanting the boron atoms 310 includes a dose of B or BF₂ of about 1E13 to 8E13 atoms/cm² and acceleration energy of about 3 to 10 kev.

E.g., consider the case where the predefined region 250 is configured as lightly doped drain pre-anneal regions, and again C atoms 240 are provided by implantation. In some embodiments, implanting C atoms 240 into the semiconductor substrate 210 includes a dose of about 4E14 to 2E15 atoms/cm² and acceleration energy of about 1 to 3 keV. Implanting the In atoms 270 includes a dose of about 1E13 to 2E14 atoms/cm² and acceleration energy of about 40 to 60 keV. Implanting the boron atoms 310 includes a dose of B or BF₂ of about4E14 to4E15 atoms/cm² and acceleration energy of about 0.5 to 3 kev.

FIG. 4 shows the device 200 of FIG. 3 after thermally annealing the semiconductor substrate 210 to transform the predefined regions 245, 250 into activated p-doped regions 410, 420, in accordance with step 120 (FIG. 1). Laser annealing, arc annealing or other forms of conventional annealing can be used to heat the substrate 210 to a temperature and for a duration sufficient to form the activated p-doped regions 410, 420. E.g., in some cases, the thermal anneal comprises heating to about 950 to 1350° C. for about 1 to 100E-6 seconds.

The structure of the activated p-doped regions 410, 420 depends upon the type of predefined region 245, 250 that was formed in the substrate 210. E.g., when the predefined region 245 (FIG. 3) is configured as halo pre-anneal regions then the activated p-doped region 410 is configured as a super steep retrograde (SSR) region. Example SSR regions are presented in the above-cited U.S. Pat. No. 7,061,058. When the predefined region 250 (FIG. 3) is configured as lightly doped drain pre-anneal regions, then the activated p-doped region 420 is configured as lightly doped drain regions.

Because the C atoms 240 (FIG. 3) retard the diffusion of In atoms 270, the concentration of In atoms 270 in the activated p-doped regions 410, 420 is higher than otherwise attainable after the thermal anneal. E.g., in some cases, the after the thermal anneal, the concentration of In atoms 270 in one or both of the activated p-doped regions 410, 420 equals at least about 1E18 atoms/cm³.

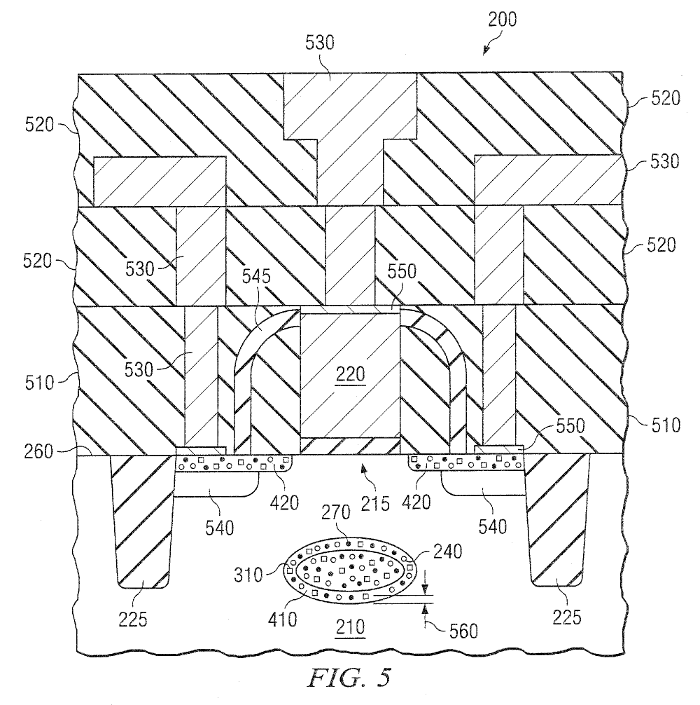

FIG. 5 shows the semiconductor device 200 (e.g., the embodiment presented in FIG. 4) after performing additional conventional fabrication steps to complete the device's 200 manufacture. In some embodiments the device 200 is, or includes, an integrated circuit. FIG. 5 shows the device 200 configured as an integrated circuit, after depositing a pre-metal dielectric (PMD) layer 510 and interlayer dielectric (ILD) layers 520 over the active device 215. FIG. 5 also shows the device 200 after forming interconnects 530 (e.g., single or dual damascene structures) through the PMD and ILD layers 510, 520 and contacting the active device 215. The active device 215 can be configured as an nMOS transistor, a pMOS transistor or combinations thereof (e.g., CMOS device). FIG. 5 also shows the device 200 after forming source and drain structures 540, gate sidewalls 545, and contact electrodes 550 of the active device 215.

FIG. 5 also illustrates another embodiment of the disclosure, a semiconductor device 200. Embodiments of the device 200 comprise one or more active devices 215 on or in a semiconductor substrate 210, wherein at least one of the active devices 215 has one or more activated p-doped regions 410, 420 that includes C atoms 240, In atoms 270 and p-type dopants 310. At least one of the activated p-doped regions 410, 420 (e.g., the SSR region 410 as shown in FIG. 5) has an abrupt boundary as characterized by a decade change in the p-dopant 410 concentration over a distance 560 of about 7 nm or less. In some embodiments, at least one of the activated p-doped regions 410, 420 has a concentration of C-atoms 240 that is equal to or greater than a sum or In atom 270 and p-dopant atom 310 concentrations E.g., in some cases the C atom 240 concentration is about 10 percent greater than the sum of the In atom 270 and boron atom 310 concentrations in the activated p-doped regions 410, 420 In other cases, however, the C atom concentration 240 after thermal annealing (step 120) is less than the sum of the In atom 270 and boron atom 310 concentrations because the C-atoms have substantially diffused throughout the substrate 210.

Those skilled in the art to which the disclosure relates will appreciate that other and further additions, deletions, substitutions, and modifications may be made to the described example embodiments, without departing from the disclosure.

What is claimed is:

1. A method of manufacturing a semiconductor device, comprising:
providing carbon atoms in a semiconductor substrate;
implanting indium atoms into a predefined region of said substrate that is configured to have said carbon atoms;
implanting p-type dopants into said predefined region; and
thermally annealing said semiconductor substrate to transform said predefined region into an activated doped region.

2. The method of claim 1, wherein said activated p-doped region has an abrupt boundary as characterized by a decade change in said p-type dopant concentration over a distance of about 7 nm or less.

3. The method of claim 1, wherein providing said carbon atoms in said predefined region includes depositing a silicon carbide layer on said semiconductor substrate.

4. The method of claim 1, wherein providing said carbon atoms in said predefined region includes forming a trench in said semiconductor substrate and then depositing a silicon carbide layer in said trench.

5. The method of claim 1, wherein providing said carbon atoms in said predefined region includes implanting carbon atoms into said semiconductor substrate.

6. The method of claim 5, wherein implanting said indium atoms into said predefined region is done before implanting said carbon atoms.

7. The method of claim 1, wherein implanting said indium atoms amorphizes a surface of said semiconductor substrate.

8. The method of claim 1, wherein a substantial number of said implanted indium atoms and said carbon atoms occupy adjacent substitutional sites in said semiconductor substrate.

9. The method of claim 1, wherein said carbon atoms impede the diffusion of said implanted indium atoms during said thermal anneal.

10. The method of claim 1, wherein a dose of said carbon atoms in said predefined region is greater than or equal to a sum of doses of said indium atoms and said p-type dopants in said predefined region.

11. The method of claim 1, wherein there is a substantially equal or greater dose of fluorine atoms implanted as said p-type dopant.

12. A method of manufacturing a semiconductor device, comprising:
forming one or more active devices on or in a semiconductor substrate, wherein at least one of said active devices is manufactured by a process that includes:
providing carbon atoms in a semiconductor substrate;
implanting indium atoms into a predefined region of said substrate that is configured to have said carbon atoms;
implanting and boron atoms into said predefined region; and
thermally annealing said semiconductor substrate to transform said predefined region into an activated p-doped region.

13. The method of claim 12, wherein said predefined region is configured as halo pre-anneal regions and said activated p-doped region is configured as a super steep retrograde region.

14. The method of claim 13, wherein providing said carbon atoms in said predefined region includes implanting carbon atoms into said semiconductor substrate includes a dose of about 1E15 to 2E15 atoms/cm² and acceleration energy of about 1 to 5 keV, implanting said indium atoms includes a dose of about 1E13 to 6E13 atom/cm² and acceleration energy of about 4 to 8 keV, and implanting said boron atoms includes a dose of boron or boron difluoride of about 1E13 to 8E13 atoms/cm² and acceleration energy of about 3 to 10 kev.

15. The method of claim 12, wherein said predefined region is configured as lightly doped drain pre-anneal regions and said activated p-doped region is configured as lightly doped drain regions.

16. The method of claim 15, wherein said predefined region is configured as lightly doped drain pre-anneal regions, and providing said carbon atoms in said predefined region includes implanting carbon atoms into said semiconductor substrate includes a dose of about 4E14 to 2E15 atoms/cm and acceleration energy of about 1 to 3 keV, implanting said indium atoms includes a dose of about 1E13 to 2E14 atoms/cm and acceleration energy of about 40 to 60 keV, and implanting said boron includes a dose of boron or boron about 4E14 to 4E15 atoms/cm² and acceleration energy of about 0.5 to 3 kev.

17. The method of claim 12, wherein after said thermal anneal, a concentration of said indium atoms in said activated p-doped region equals at least about 1E18 atoms/cm³.

18. The method of claim 12, wherein said semiconductor device configured an integrated circuit, and further comprises:
depositing pre-metal and interlayer dielectric layers over said at least one active device; and
forming interconnects through said pre-metal and interlayer dielectric layers and contacting said at least one active device.

19. A semiconductor device, comprising:
one or more active devices on or in a semiconductor substrate, wherein at least one of said active devices has one or more activated p-doped regions that includes carbon atoms, indium atoms and p-type dopants.

20. The method of claim 19, wherein at least one of said activated p-doped regions has an abrupt boundary as characterized by a decade change in said p-dopant concentration over a distance of about 7 nm or less.

21. The method of claim 19, wherein at least one of said activated p-doped regions has a concentration of carbon atoms that is equal to or greater than a sum of indium and p-dopant atom concentrations.
